(19) United States
(12) Patent Application Publication
(10) Pub. No.: US 2014/0285180 A1
(43) Pub. Date: Sep. 25, 2014

(54) Circuit to Compensate for Inaccuracies in Current Transformers

(71) Applicant: NATIONAL INSTRUMENTS CORPORATION, Austin, TX (US)

(72) Inventor: Garritt W. Foote, Austin, TX (US)

(73) Assignee: National Instruments Corporation, Austin, TX (US)

(21) Appl. No.: 13/849,761

(22) Filed: Mar. 25, 2013

(51) Int. Cl. G01R 19/32; H03H 11/52; G01R 19/00

(52) U.S. Cl. CPC G01R 19/32; G01R 19/0092; H03H 11/52
USPC 324/105; 324/127; 333/217

(57) ABSTRACT

An improved measurement circuit includes a current transformer and an active feedback circuit operated as a negative resistance that matches the value of the winding resistance of the current transformer. An amplifier in the feedback circuit provides power to drive a secondary current through a sense resistor and the transformer winding resistance, reducing the most significant error source in a current transformer circuit by presenting a negative impedance to the current transformer. Combined with the positive resistance of the transformer's winding, the negative impedance results in a net burden of zero on the current transformer, which eliminates the need for the transformer having to provide power to drive the secondary current. This facilitates the use of smaller transformers while achieving reduced measurement errors. Thus, a single, compact measurement device may be used in a wide range of applications with high measurement performance.

### FIELD OF THE INVENTION

The present invention relates to the field of instrumentation, and more particularly to compensating for inaccuracies in current transformers used in performing measurements for power monitoring.

### DESCRIPTION OF THE RELATED ART

In many industrial applications (and others), instruments collect data or information from an environment or unit under test (UUT), and may also analyze and process acquired data. Some instruments provide test stimuli to a UUT. Examples of instruments include oscilloscopes, digital multimeters, pressure sensors, arbitrary waveform generators, digital waveform generators, etc. The information that may be collected by respective instruments includes information describing voltage, resistance, distance, velocity, pressure, oscillation frequency, humidity, and/or temperature, among others. Computer-based instrumentation systems typically include transducers for capturing a physical phenomenon and generating a representative electrical signal, signal conditioning logic to perform amplification on the electrical signal, isolation, and/or filtering, and analog-to-digital (A/D) conversion logic for receiving analog signals and providing corresponding digital signals to the host computer system.

In a computer-based system, the instrumentation hardware or device is typically an expansion board plugged into one of the I/O slots of the computer system. In another common instrumentation system configuration, the instrumentation hardware is coupled to the computer system via other means such as through a VXI (VME extensions for Instrumentation) bus, a GPIB (General Purpose Interface Bus), a PXI (PCI extensions for Instrumentation) bus, Ethernet, a serial port or bus, or parallel port of the computer system. The instrumentation hardware may include a DAQ (Data Acquisition) board, a computer-based instrument such as a multimeter, or another type of instrumentation device. In another common system configuration, a chassis and boards inserted in the chassis may operate as a standalone instrument or instrument suite, although in some cases a host computer may be used to configure or program the boards prior to, or during operation.

The instrumentation hardware may be configured and controlled by software executing on a host computer system coupled to the system, or by a controller card installed in the chassis. The software for configuring and controlling the instrumentation system typically includes driver software and the instrumentation application software, or the application. The driver software serves to interface the instrumentation hardware to the application and is typically supplied by the manufacturer of the instrumentation hardware or by a third party software vendor. The application is typically developed by the user of the instrumentation system and is tailored to the particular function that the user intends the instrumentation system to perform. The instrumentation hardware manufacturer or third party software vendor sometimes supplies application software for applications that are common, generic, or straightforward. Instrumentation driver software provides a high-level interface to the operations of the instrumentation device. The instrumentation driver software may operate to configure the instrumentation device for communication with the host system and to initialize hardware and software to a known state. The instrumentation driver software may also maintain a soft copy of the state of the instrument and initiated operations. Further, the instrumentation driver software communicates over the bus to move the device from state to state and to respond to device requests.

The accuracy of the electronic components used in common measurement devices or instruments, for example current transformers in current-monitoring circuits, can vary. Current Transformers are commonly used in measuring circuits for monitoring power line currents. They provide a level of isolation, present a low burden to the circuit being measured, tolerate high fault currents, and present a higher signal level to the rest of the measurement system than a simple shunt resistor would. In a typical current transformer circuit, the signal being measured (the transformer primary current, I_{P}) provides the power needed to drive a stepped-down secondary current (I_{S}) through a winding resistance of the current transformer and a sense resistor (R_{S}). The power transfers through the magnetic flux of the core of the current transformer, which unfortunately does not provide a 100% efficient and error free transfer. The inaccuracies of current transformers can manifest themselves in bandwidth, dynamic range, phase shift, and gain errors depending on the transformer design and materials used. Consequently, modern power measurement devices often come in a family of options, each tailored for particular measurement challenges. Even within these options, physically large current transformers, and sometimes multiple current transformers, are used to minimize the errors of the power transfer.

Other corresponding issues related to the prior art will become apparent to one skilled in the art after comparing such prior art with the present invention as described herein.

### SUMMARY OF THE INVENTION

In one set of embodiments, an improved measurement circuit—used for monitoring power line currents, for example—may include a current transformer, and may also include an active feedback circuit that simulates a negative resistance, in lieu of including a simple shunt resistance. The feedback circuit may operate as a negative resistance matching the value of the winding resistance of the current transformer, and may include an amplifier to provide power to drive a secondary current through a sense resistor and the transformer winding resistance. This eliminates the reliance on the lossy, error prone power transfer that would otherwise have to be provided by the current transformer during measurements performed using the current transformer. Various embodiments of an improved measurement circuit may thereby reduce the most significant error source in a current transformer circuit by presenting a negative impedance to the current transformer, which, combined with the positive resistance of the transformer's winding, results in a net burden of zero on the current transformer, eliminating the need for the transformer having to provide power to drive the secondary current. This facilitates the use of smaller transformers while achieving a smaller measurement error than would typically be present in conventional designs. Thus, a single, compact measurement device may be used in a wide range of applications with high measurement performance.

Therefore, in one embodiment, a feedback circuit includes a first terminal for coupling to a first end of two ends of a conductor winding, and also includes a second terminal for coupling to a second end of the two ends of the conductor winding. The feedback circuit may be operated to develop a negative resistance across the two ends of the conductor winding by driving a secondary current in the conductor winding, with the absolute value of the negative resistance matching the value of the resistance of the conductor winding. The conductor winding may be wound around a magnetic core to operate as a current transformer, with the feedback circuit driving the secondary current in the conductor winding responsive to changes in the magnetic flux developed in the magnetic core in response to a primary current flowing in a conductor passed through the magnetic core.

In some embodiments, the feedback circuit includes an amplifier having an input coupled to the second terminal and an output coupled to the first terminal, with the amplifier operated to force a derivative of the magnetic flux to zero by forcing an inductance voltage of the conductor winding to zero while driving the secondary current in the conductor winding. The feedback circuit may also include an AC coupling network coupled between the second terminal and the first input of the amplifier to force a DC current in the conductor winding to zero. In addition, a sense resistor may be coupled to the second terminal to develop an input voltage at the second terminal by conducting the sense current, with the amplifier amplifying the input voltage, and driving the amplified version of the input voltage at the first terminal. This results in a transformer voltage developed across the first terminal and the second terminal, with the transformer voltage having a value equivalent to a value of the secondary current multiplied by the value of the resistance of the conductor winding.

In addition, the gain of the amplifier may be set with a resistor circuit coupled between a second input of the amplifier and the output of the amplifier. A first resistance in the resistance circuit may have its first terminal coupled to the second input of the amplifier, and its second terminal coupled to the output of the amplifier, and may have a value equivalent to a multiple of the value of the resistance of the conductor winding. A second resistor in the resistance circuit may have a first terminal coupled to the second input of the amplifier, and a second terminal coupled to a voltage reference, and may have a value equivalent to a multiple of the value of the sense resistor. The feedback circuit may also include a programmable digital potentiometer for reducing a baseline (i.e. not temperature dependent) uncertainty of the conductor winding, and/or a thermistor for reducing or compensating for an uncertainty caused by a temperature change of the conductor winding.

Accordingly, a method may be developed for performing measurements using a circuit with a current transformer having a magnetic core and a conductor winding around the magnetic core. The method includes driving a secondary current in the conductor winding through a feedback circuit (which has a first terminal of two terminals coupled to a first end of two ends of the conductor winding, and a second terminal of the two terminals coupled to a second end of the two ends of the conductor winding), developing a negative resistance across the two ends of the conductor winding responsive to driving the secondary current, with an absolute value of the negative resistance matching the value of the resistance of the conductor winding. The method may also include driving a primary current in a conductor passed through the magnetic core, in which case the secondary current in the conductor winding is driven in response to changes in the magnetic flux developed in the magnetic core in response to the conductor conducting the primary current.

In some embodiments, developing the negative resistance may include forcing a derivative of a magnetic flux developed in the magnetic core to zero, by forcing an inductance voltage of the conductor winding to zero while driving the secondary current in the conductor winding. In addition, a DC current in the conductor winding may also be forced to zero, to eliminate DC error effects. In addition, developing the negative resistance may include developing an input voltage at the second terminal by having a sense resistor conduct the sense current, and developing a transformer voltage across the first terminal and the second terminal by amplifying the input voltage, and driving the amplified version of the input voltage at the first terminal, with the transformer voltage having a value equivalent to the value of the secondary current multiplied by the value of the resistance of the conductor winding. The amplification may be performed using an amplifier circuit that includes

an amplifier having a first input to receive the input voltage, also having a second input, and having an output coupled to the first terminal. The amplifier circuit may include a resistor circuit coupled between the second input of the amplifier and the output of the amplifier, to set a gain of the amplifier. The method may also include reducing a temperature uncertainty of the conductor winding through a programmable digital potentiometer coupled in the resistor circuit, and/or reducing a temperature change of the conductor winding through a thermistor coupled in the resistor circuit.

Other aspects of the present invention will become apparent with reference to the drawings and detailed description of the drawings that follow.

### BRIEF DESCRIPTION OF THE DRAWINGS

A better understanding of the present invention can be obtained when the following detailed description of the preferred embodiment is considered in conjunction with the following drawings, in which:

FIG. 1 shows an instrumentation control system with instruments networked together according to one embodiment of the invention;

FIG. 2 shows an industrial automation system with instruments networked together according to one embodiment of the invention;

FIG. 3 shows a diagram illustrating a magnetic field generated by a primary current passing through a conductor;

FIG. 4 shows a diagram illustrating the magnetic flux generated in a magnetic core when the conductor is looped through the opening of the magnetic core;

FIG. 5 shows a diagram illustrating a secondary current flowing in additional windings that are wrapped around the magnetic core, and are attached to a circuit that completes their current path;

FIG. 6 shows a diagram illustrating the use of a magnetic flux sensor and an additional winding on the magnetic core to correct for errors in a current transformer;

FIG. 7 shows the circuit diagram of a prior art measurement circuit that uses a current transformer and a shunt resistor;

FIG. 8 shows the circuit diagram of the prior art measurement circuit of FIG. 7, with an equivalent circuit for the current transformer;

FIG. 9 shows one embodiment of a measurement circuit that uses a current transformer with an active negative resistance feedback circuit that matches the winding resistance of the current transformer;

FIG. 10 shows the circuit diagram of the measurement circuit of FIG. 9, with an equivalent circuit for the current transformer;

FIG. 11 shows a plot illustrating the phase vs. frequency response of three different embodiments of a measurement circuit that uses a current transformer;

FIG. 12 shows a gain error plot for the three different embodiments of a measurement circuit that uses a current transformer;

FIG. 13 shows measurement waveforms taken for a specified primary current with varying amounts of DC bias for a measurement circuit that uses a large current transformer and a simple shunt resistance;

FIG. 14 shows measurement waveforms taken for a specified primary current with varying amounts of DC bias for a measurement circuit that uses a small current transformer and a simple shunt resistance;

FIG. 15 shows measurement waveforms taken for a specified primary current with varying amounts of DC bias for a measurement circuit that uses a small current transformer and an active negative resistance feedback circuit instead of a simple shunt resistance;

FIG. 16 shows the circuit diagram of the measurement circuit of FIG. 10 with added components for temperature stability and calibration;

FIG. 17 shows voltage plots of drive voltage and inductor voltage vs. secondary current when using an output voltage limiting output stage to drive the current transformer; and

FIG. 18 shows the circuit diagram of one embodiment of an amplifier output stage used to drive the current transformer.

While the invention is susceptible to various modifications and alternative forms, specific embodiments thereof are shown by way of example in the drawings and are herein described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE EMBODIMENTS

Embodiments of the present invention may be used in systems configured to perform test and/or measurement functions, to control and/or model instrumentation or industrial automation hardware, or to model and simulate functions, e.g., modeling or simulating a device or product being developed or tested, etc. More specifically, it may be used in various instances where input protection for instrumentation equipment is required, without degrading the performance of the protected instrumentation equipment. However, it is noted that the present invention may equally be used for a variety of applications, and is not limited to the applications enumerated above. In other words, applications discussed in the present description are exemplary only, and the present invention may be used in any of various types of systems. Thus, the system and method of the present invention may be used in any number of different applications. It is noted that the various terms or designations for circuits/components as they appear herein, such as “feedback circuit”, “measurement circuit”, etc. are merely names or identifiers used to distinguish among the different circuits/components, and these terms are not intended to connote any specific, narrowly construed meaning.

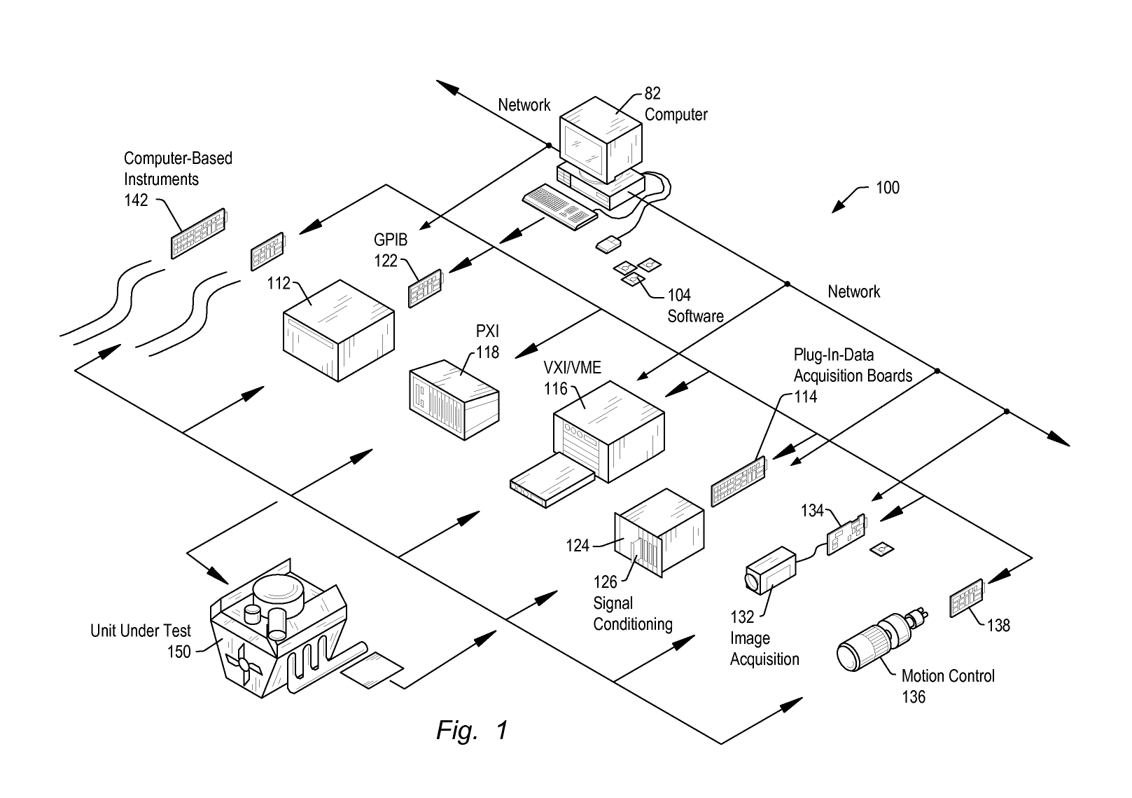

FIG. 1 illustrates an exemplary instrumentation control system 100 which may be configured according to embodiments of the present invention. System 100 comprises a host computer 82 which may couple to one or more instruments configured to perform a variety of functions using timing control implemented according to various embodiments of the present invention. Host computer 82 may comprise a CPU, a display screen, memory, and one or more input devices such as a mouse or keyboard as shown. Computer 82 may operate with one or more instruments to analyze, measure, or control a unit under test (UUT) or process 150. The one or more instruments may include a GPIB instrument 112 and associated GPIB interface card 122, a data acquisition board 114 inserted into or otherwise coupled with chassis 124 with associated signal conditioning circuitry 126, a VXI instrument 116, a PXI instrument 118, a video device or camera 132 and associated image acquisition (or machine vision) card 134, a motion control device 136 and associated motion control interface card 138, and/or one or more computer based instrument cards 142, among other types of devices.

The computer system may couple to and operate with one or more of these instruments. In some embodiments, the computer system may be coupled to one or more of these instruments via a network connection, such as an Ethernet connection, for example, which may facilitate running a high-level synchronization protocol between the computer system and the coupled instruments. The instruments may be coupled to the unit under test (UUT) or process 150, or may be coupled to receive field signals, typically generated by transducers. System 100 may be used in a data acquisition and control applications, in a test and measurement application, an image processing or machine vision application, a process control application, a man-machine interface application, a simulation application, or a hardware-in-the-loop validation application, among others.

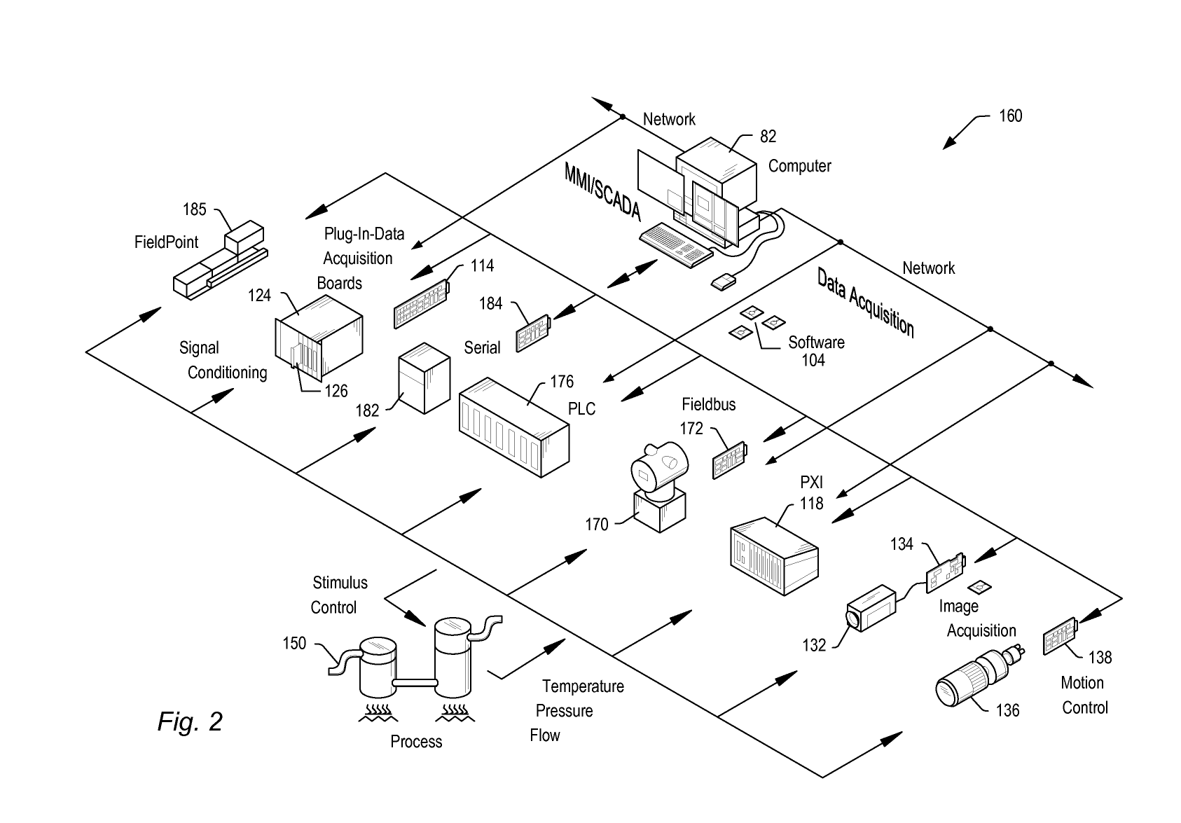

FIG. 2 illustrates an exemplary industrial automation system 160 that may be configured according to embodiments of the present invention. Industrial automation system 160 may be similar to instrumentation or test and measurement system 100 shown in FIG. 2A. Elements that are similar or identical to elements in FIG. 1 have the same reference numerals for convenience. System 160 may comprise a computer 82 which may couple to one or more devices and/or instruments configured to perform a variety of functions using timing control implemented according to various embodiments of the present invention. Computer 82 may comprise a CPU, a display screen, memory, and one or more input devices such as a mouse or keyboard as shown. Computer 82 may operate with the one or more devices and/or instruments to perform an automation function, such as MMI (Man Machine Interface), SCADA (Supervisory Control and Data Acquisition), portable or distributed data acquisition, process control, and advanced analysis, among others, on process or device 150.

The one or more devices may include a data acquisition board 114 inserted into or otherwise coupled with chassis 124 with associated signal conditioning circuitry 126, a PXI instrument 118, a video device 132 and associated image acquisition card 134, a motion control device 136 and associated motion control interface card 138, a field bus device 170 and associated field bus interface card 172, a PLC (Programmable Logic Controller) 176, a serial instrument 182 and associated serial interface card 184, or a distributed data acquisition system, such as the Compact FieldPoint or CompactRIO systems available from National Instruments, among other types of devices. In some embodiments, similar to the system shown in FIG. 1, the computer system may couple to one or more of the instruments/devices via a network connection, such as an Ethernet connection.

In some embodiments, measurement or measuring instruments and devices, such as those shown in FIG. 1, may include a measurement circuit that contains a current transformer to monitor power line current, for example. As previously mentioned, current transformers provide a level of isolation, present a low burden to the circuit being measured, tolerate high fault currents, and present a higher signal level than a simple shunt resistor to the rest of the measurement system. A brief analysis of the operating principle of a transformer-based measurement is provided below.

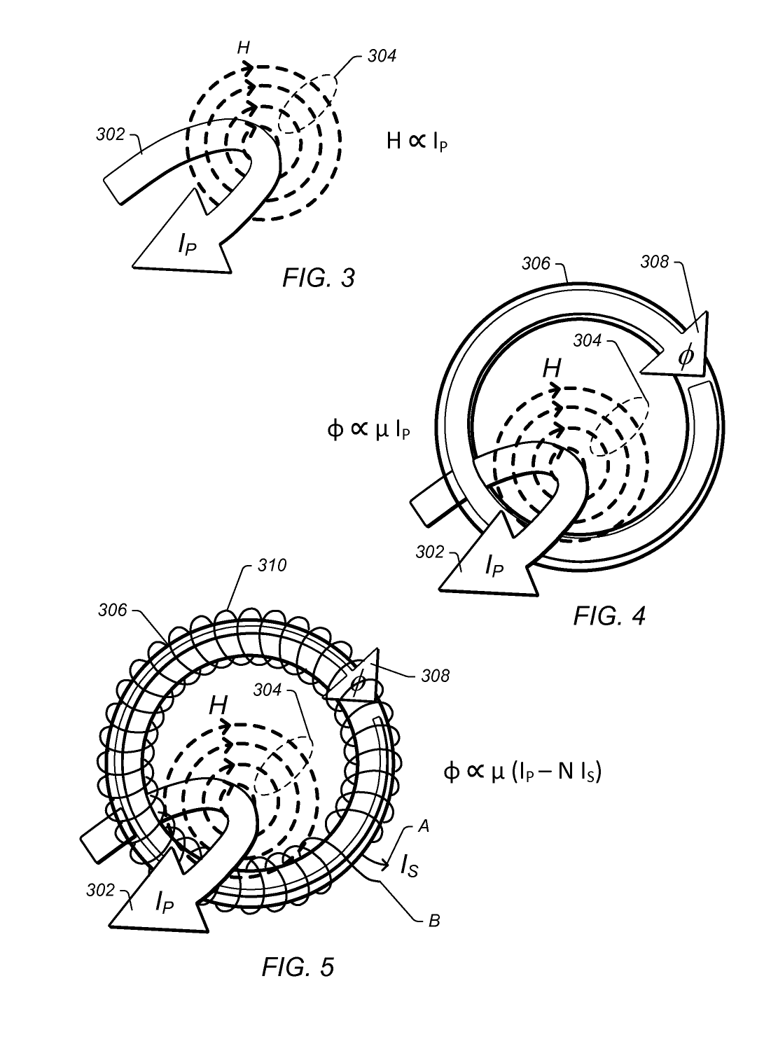

As illustrated in FIG. 3, when a primary current 302 (Iₚ) is passed through a conductor, the current generates a magnetic field 304 (H) around the conductor, with the intensity of the magnetic field 304 proportional to the magnitude of the primary current 302, as also indicated in FIG. 3. As illustrated in FIG. 4, when the conductor is looped through the opening of a magnetic core 306, a magnetic flux 308 (Φ) is generated in the core 306, with the magnitude of the magnetic flux 308 proportional to the permeability (μ) of the core 306 multiplied by the magnetic field density (H), as also indicated in FIG. 4. As illustrated in FIG. 5, when additional windings 310 are wrapped around the core 306, the changes in the flux generate voltages in each of the windings 310. If the windings 310 are attached—via terminals A and B—to a circuit that can complete their current path, then the generated voltage causes a secondary current (Iₛ) to flow in the windings 310. The direction of the secondary current causes a magnetic field (corresponding to the secondary current) that tends to cancel out the magnetic field 304 caused by (or corresponding to) the primary current 302. However, there is a residual remaining magnetic flux that is just sufficient enough to provide the driving force for the secondary current, and is proportional to the permeability of the core (μ) multiplied by the difference between the primary current 302 (Iₚ) and the number of windings 310 or turns (N) multiplied by the secondary current (Iₛ), as also indicated in FIG. 5. Ideally, the residual flux is expected to be zero, and the secondary current is expected to be a faithful representation of the primary current where Iₛ=Iₚ÷N. Instead, the residual flux represents the error in the secondary current as a measure of the primary current.

A typical measurement circuit that uses a current transformer is shown in FIG. 7. The circuit 200 may use a transformer 204 to measure a current provided by current source 202. The signal being measured (the transformer primary current, I_{P}) may provide the power needed to drive the stepped-down secondary current (I_{S}) through the winding resistance of the current transformer 204 (having a 1:N primary winding to secondary winding ratio) and the sense resistor (R_{S}) 206. The power is transferred through the magnetic flux of the core of the current transformer 204. However, measurement circuit 200 does not provide a 100% efficient and error free transfer. An equivalent circuit 250 of circuit 200 from FIG. 7 is shown in FIG. 8, with a (equivalent) current transformer 218 driving sense resistor (Rₛ) 206. The inductance (L) 214 and the current flowing through it (I_{L}) represent the residual flux in the core. As the secondary current I_{S} flows through the winding resistance (R_{L}) 216 and the sense resistor 206, it develops a voltage that is seen by the internal inductance 214 of the transformer. The developed voltage causes current to flow through the inductor 214. The current flowing through inductance 214 may therefore be expressed as:

I_{L}=I_{S}(R_{L}+R_{S})/jωL.

The inductor current (I_{L}) represents the error in the secondary current (I_{S}) as a measure of the primary current (I_{P}). For a fixed value of inductance 214, the error manifests itself as a first order high-pass filter. However, inductance 214 is proportional to the permeability μ of the core, and is nonlinear with respect to either frequency or amplitude. As a result, the secondary current I_{S} is prone to gain error and phase error, which can vary with both signal level and frequency.

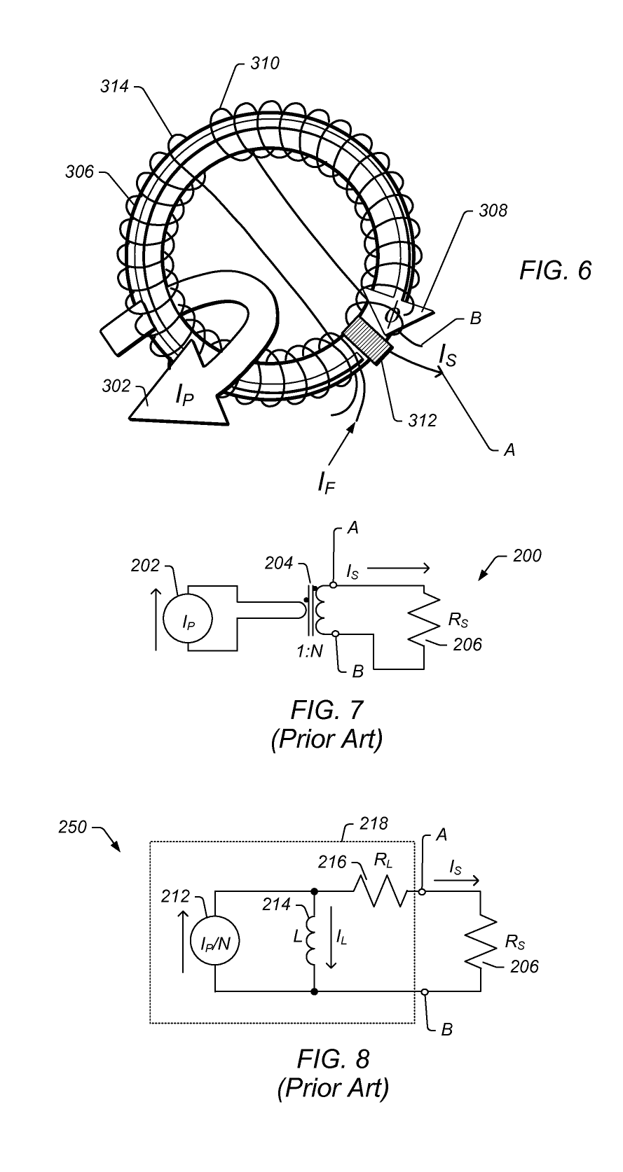

Furthermore, a given core may only sustain a certain amount of magnetic flux before it saturates and ceases to operate as a transformer. According to the selection of core geometry, material, and windings, a current transformer typically exhibits characteristics that represent a balance, to varying degrees, between at least the following limitations: large size, non-linear errors, gain errors and phase shifts, limited signal range, and intolerance to DC currents. As illustrated in FIG. 6, one method of correcting for the errors in a current transformer is to use a magnetic flux sensor 312 (such as a Hall effect sensor) in the core 306 along with an additional winding 314 on the core 306. A feedback circuit (not shown) may then be used to drive the additional winding with the current (I_{F}) needed to reduce the residual flux to zero. Such closed-loop, active feedback current transformers have the advantage of being able to measure DC currents, but this advantage comes with increased cost and size, and the circuit requires power to drive coil 314 and obtain measurements from sensor 312.

In one set of embodiments, a novel measurement circuit featuring a transformer may be designed with a circuit implementing a negative sense resistance having a(n absolute) value commensurate with the effective value of the winding resistance of the current transformer. Referring to circuit 250, the novel circuit may be characterized as circuit 250 including a sense resistor 206 such that R_{S}=−R_{L}. Such a configuration keeps the voltage across the inductance 214 at approximately zero (0) volts, resulting in the flux (and the error current I_{L} that it represents) also becoming approximately zero:

I_{L}=I_{S}(R_{L}+R_{S})/jωL=I_{S}(R_{L}−R_{L})/jωL≈0.

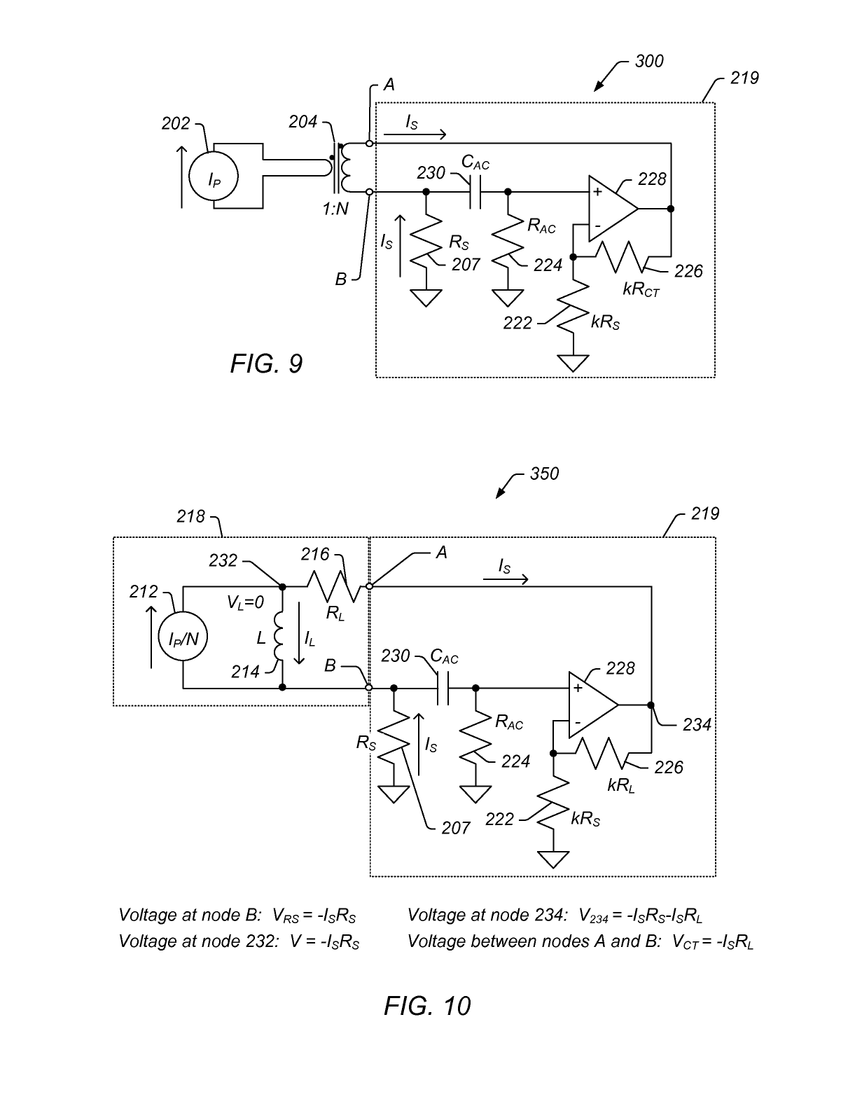

In practice, the error current may not be reduced to exactly zero, but rather it may be reduced to at least a specified (maximum) level according to (or dependent on) how well the negative sense resistance is matched to the winding resistance 216 (R_{L}). One embodiment of a proposed measurement circuit 300 that includes a circuit 219 implementing a negative sense resistance having a(n absolute) value matching the value of winding resistance 216 is shown in FIG. 9. FIG. 10 shows an equivalent circuit 350 representing circuit 300, with current transformer 204 represented by equivalent transformer circuit 218 (as also shown in FIG. 8). Circuit 300 (350) has many of the benefits of the closed-loop magnetic sensor designs, but without the increased size and cost that come from the extra winding and magnetic sensor. Circuit 219 represents one embodiment of an actual circuit used to implement a negative impedance having a value that matches the value R_{L} of wire resistance 216 of current transformer 204.

Referring now to FIG. 10, when conducting a measurement using circuit 350, a secondary current I_{S} flows through a sense resistor 207, developing a voltage drop V_{RS} at node B. This resulting voltage drop V_{RS} has a value of −I_{S}R_{S}, and is AC coupled and amplified with a gain of (1+R_{L}/R_{S}) by amplifier 228. The gain is provided via a feedback path that includes resistors 226 and 222 having values that are equal multiples of R_{L} and R_{S}, respectively (indicated as k R_{L} and k R_{S}). The resulting voltage developed at node 234 (V₂₃₄=−I_{S}R_{S}−I_{S}R_{L}) is applied to the other terminal (A) of the current transformer, resulting in a voltage V_{CT} developed across the transformer (i.e. between nodes A and B) that is equal to −I_{S}R_{L}. This means that the transformer sees a negative impedance of −R_{L}, and the voltage across the inductance 214 of the transformer is reduced to approximately zero, or to at least a specified (maximum) value, or lower. Effectively, circuit 219 operates by having amplifier 234 provide the driving force to push the secondary current I_{S} through the winding and sense resistances (R_{L}+R_{S}), whereas in typical present day measurement circuits that use a current transformer, the residual flux in the core with all its nonlinearities provides this driving force.

In other words, unlike closed-loop magnetic sensor designs, which directly measure the magnetic field and use feedback to force the flux to zero, circuit 350—through matching-negative-resistance circuit 219—uses amplifier 228 as a feedback to force the inductance voltage and therefore the flux derivative to zero. Accordingly, the voltage across inductance 214 may be expressed as:

V_{L}=NΦ′=jωNΦ=0,

from which it follows that Φ_{AC}=0.

As detailed above, circuit 219 may be considered to be an active negative resistance intended to match the resistance of R_{L} 216 in value, to force the inductance voltage V_{L} to zero, which in turn forces the AC component of the flux to zero. However, there is also a need to control the DC component of the flux, which may be accomplished by an AC coupling network that includes capacitance C_{AC} 230 and resistance R_{AC} 224, which ensures that there is no DC flux from the feedback circuit, or feedback at low frequency, by forcing the DC current to zero. That is, the AC coupling network (C_{AC} and R_{AC}) is used to force the DC voltage across L 214 to be zero, which forces the DC current to zero, and also stabilizes amplifier 228. Because this technique nulls (or eliminates) the derivative of the flux, and not the flux directly—the latter being the case for closed loop magnetic sensor designs—circuit 350 may be primarily used to perform AC current measurements, much like simple current transformers. Overall, circuit 350 has the benefit of not carrying the burden of magnetic sensors or an additional winding.

Using a Measurement Circuit with a Current Transformer and Active Negative Resistance

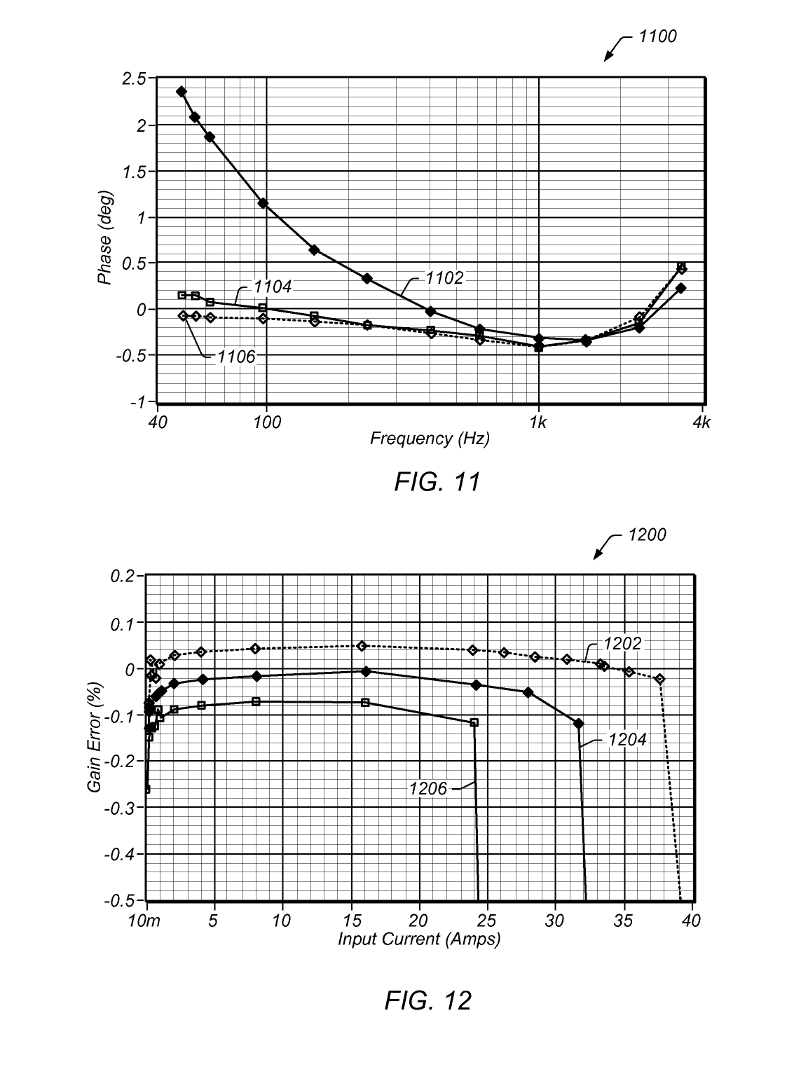

As a means of comparison, the performance of a 6.8 cm³ current transformer used in a power quality measurement circuit of a leading vendor may be compared to the performance of a smaller, 2.6 cm³ transformer. The comparison results are presented in the graphs shown in FIGS. 11-15. The smaller transformer is made of a material that allows it to handle higher currents before saturation, and in particular to handle higher DC currents without saturation, but at the expense of inaccuracies that make it unsuitable for accurate measurement applications. The graphs in FIGS. 11-15 show the performance of both the larger transformer (6.8 cm³) and the smaller (2.6 cm³) transformer in a standard current transformer (CT) configuration, along with the smaller transformer used in conjunction with an active negative resistance (or compensation) circuit, such as circuit 219.

FIG. 11 shows a plot 1100 illustrating the phase vs. frequency performance of the transformers. Curve 1102 represents the phase vs. frequency change for the small CT in a circuit with a simple shunt resistor, curve 1104 represents the phase vs. frequency change for the large CT in a circuit with a simple shunt resistor, and curve 1106 represents the phase vs. frequency change for the small CT in a circuit with an active negative resistance feedback circuit replacing the simple shunt resistor. As seen in FIG. 11, the phase errors of the small CT used with a standard shunt load are significantly worse than the phase errors of the large CT used with a standard shunt load, especially at the critical 50 Hz and 60 Hz frequencies of power line carriers. But with the addition of the novel feedback circuit, the performance of the smaller CT is on par with the performance of the much larger CT (without the novel feedback circuit).

A gain error plot 1200 in FIG. 12 shows the gain vs. input current performance at 50 Hz for the three circuit configurations discussed above. Curve 1204 represents the gain vs. input current change for the small CT in a circuit with a simple shunt resistor, curve 1206 represents the gain vs. input current change for the large CT in a circuit with a simple shunt resistor, and curve 1202 represents the gain vs. input current change for the small CT in a circuit with an active negative resistance feedback circuit replacing the simple shunt resistor. As seen in FIG. 12, the large CT is only useful up to 24 Amps (the product in which the large CT is configured is rated to 22 Amps). The smaller CT with its core material having more saturation resistance is able to push this out to 31 Amps, and with the addition of the feedback (active negative resistance) circuit, the input current may reach higher current levels, limited by the amplifier drive strength in this example to 38 Amps. With higher power amplifiers, the same CT may reach even higher current levels.

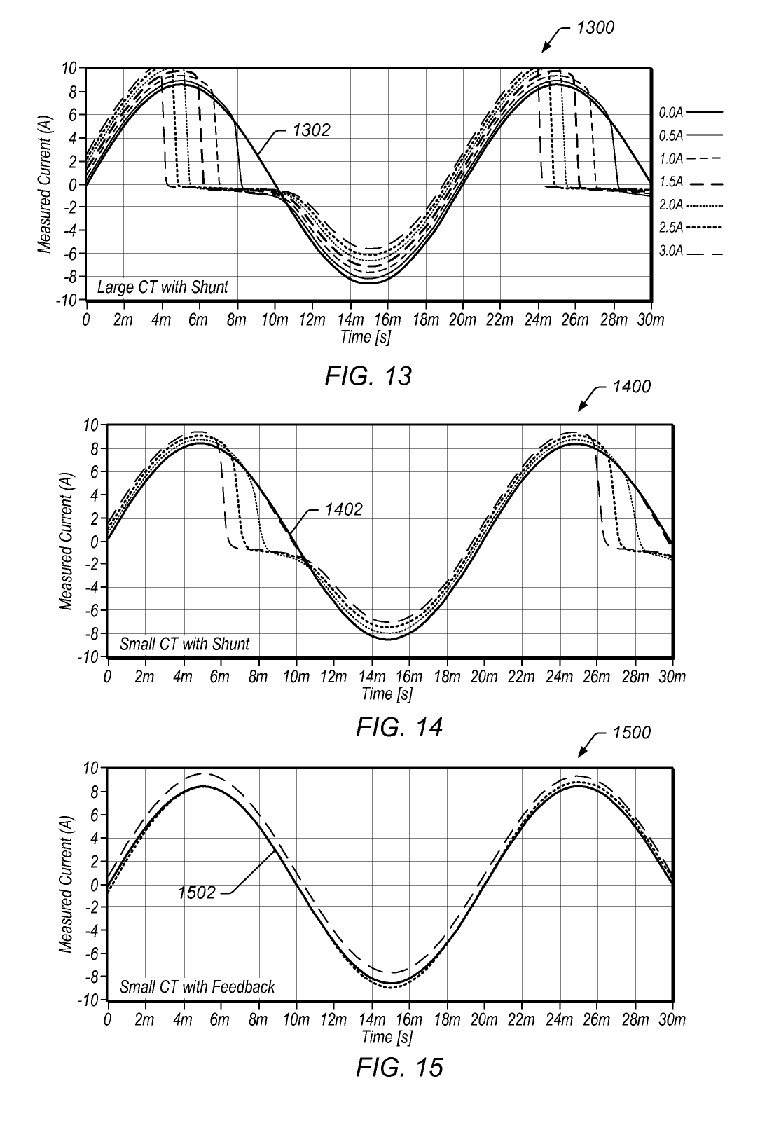

The set of plots in FIGS. 13-15 show measurement waveforms taken for the three CT circuit options (as described above) for a 6 Amps, 50 Hz primary current with varying amounts of DC bias. Graph 1300 corresponds to the large CT circuit that includes a simple shunt resistor, graph 1400 corresponds to the small CT circuit that includes a simple shunt resistor, and graph 1500 corresponds to the small CT circuit that includes a feedback (active negative resistance) circuit instead of a simple shunt resistor. The solid curve in each graph (1302, 1402, and 1502, respectively) represents a measurement taken when no DC bias is present, that is, when the DC current is 0 A. The legend for the different current values and corresponding graphical representations shown to the right of graph 1300 in FIG. 13. As seen in FIG. 13, when even 0.5 Amps of DC current is present in the circuit with the large CT, the measurements become grossly distorted, and the measurement circuit using the large CT is limited to taking measurements in systems where no DC component is present in the primary current. As seen in FIG. 14, the measurement circuit containing the smaller CT with its different core material is immune to up to 1.5 Amps of DC bias. Finally, as seen in FIG. 15, with the addition of the feedback circuit to the measurement circuit containing the small CT (where the AC flux isn't present to compete with the DC flux), the measurement circuit gains immunity to 2 Amps DC, and the distortion becomes minor even with higher DC bias.

As mentioned above, the circuit technique described herein is based on the negative impedance of a feedback circuit being equal in magnitude to the winding resistance of the current transformer. Simply designing the circuit (e.g. circuit 219) based on the nominal values of the current transformer may reduce the flux to one-tenth the value that the flux may have in a traditional shunt configuration. However, this reduction in flux may be further improved with calibration and temperature compensation. Various embodiments of improved CT measurement circuits using the active negative resistance feedback circuit may be implemented with a smaller current transformer having a core that was designed for saturation immunity rather than measurement accuracy, while still achieving the measurement performance of a larger current transformer. Therefore, various embodiments of such circuits may be smaller, with a wider input range, and with much better DC immunity than present day traditional CT measurement circuits.

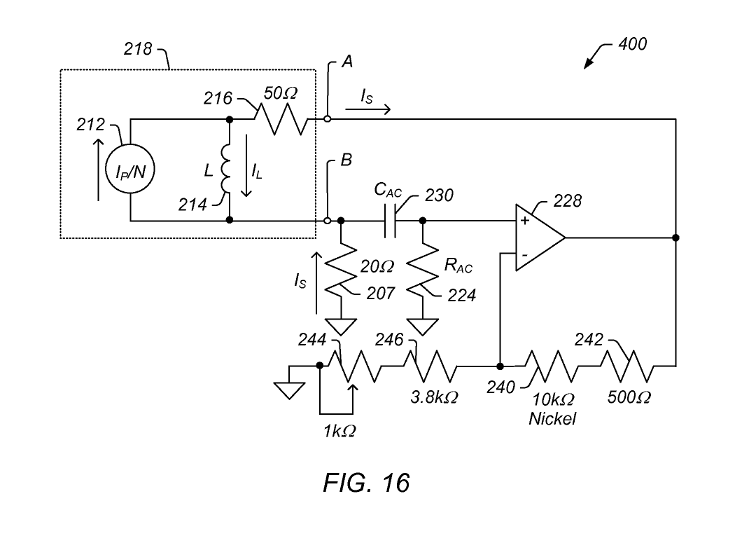

FIG. 16 shows another embodiment 400 of a CT measurement circuit, where components have been added to circuit 219 for calibration and temperature compensation. With the example resistance values shown in FIG. 16, the incorporation of a 1 kΩ digital trimpot 244 (i.e., a programmable digital potentiometer, such as the AD5273, for example) as shown in FIG. 16, the room temperature uncertainty of a 50Ω winding may be reduced from ±5Ω to ±0.2Ω. The use of a Nickel thermistor 240 added in the amplifier feedback path may match the 0.2Ω/° C. temperature change of the copper winding to within ±0.02Ω/° C., which represents a reduction by at least a factor of 10. In other words, thermistor 240 may provide temperature independence by providing a temperature tracking resistance (together with resistor 242). As a result, the total load resistance that the flux of the current transformer uses to drive the current may be reduced to ±1.5Ω over a temperature range of −40° C. to +85° C. That's about 50 times less than the resistance that would be required if the current transformer had to drive a 20Ω sense resistor without the feedback circuitry (i.e. without circuit 219, for example), and results in 50 times less residual flux. Of course other embodiments may use different values for the resistors 207, 224, 246, and 242, thermistor 240, and trimpot 244 depending on the type and size of the current transformer used (which determines the winding resistance 216 and inductance 214).

It should be noted that a potential cost of the benefits conferred by various embodiments of an active negative resistance feedback circuit in a CT measurement circuit may be power. In a traditional CT measurement circuit design with a simple shunt resistor, the primary current provides the power (through the flux of the core) to drive the sense current through the winding and shunt resistances. In the embodiments disclosed herein, that power is provided from the amplifier (e.g. amplifier 228). With the example small CT described previously, there were 1500 secondary turns with a 38 Amp input current range, which might reasonably call for a ±40 mA range of secondary currents.

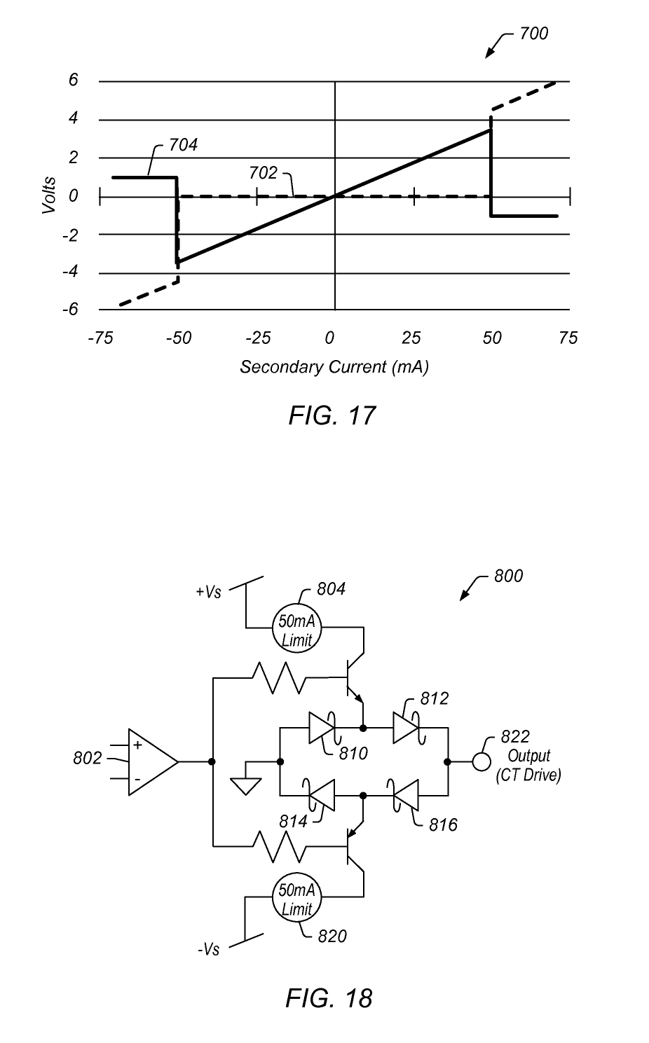

FIG. 18 shows a circuit diagram of one embodiment of an output stage of the amplifier 228 that may be used to drive the transformer 204. Amplifier 802 represents the bulk of the circuitry of amplifier 228, while the remaining components are part of the output stage driving transformer 204, as shown in FIGS. 9, 10, and 16, for example. With 50 mA current limits on each supply (804 and 820), the amplifier may support peak secondary currents of ±40 mA cleanly, with currents above 50 mA being limited by the current limiters to prevent excessive power consumption from the rails. The output voltage at node 822 may quickly shut off, and the diode bridge—including diodes 810-816—may route the secondary current flow to ground rather than through either of the supplies 804 and 820. This may result in a large voltage developed across the inductance (214) of the transformer, which in turn may cause the flux in the core to begin rising until it saturates and distorts the secondary current, as illustrated in graph 700 shown in FIG. 17. Curve 704 represents the drive voltage at node 822, and curve 702 represents the inductor voltage across inductance 214. A greater measurement current range may require more power from larger supplies and with higher current limits.

Although the embodiments above have been described in considerable detail, numerous variations and modifications will become apparent to those skilled in the art once the above disclosure is fully appreciated. It is intended that the following claims be interpreted to embrace all such variations and modifications.

We claim:

1. A feedback circuit comprising:
a first terminal configured to couple to a first end of two ends of a conductor winding; and
a second terminal configured to couple to a second end of the two ends of the conductor winding;
wherein the feedback circuit is configured to develop a negative resistance across the two ends of the conductor winding by driving a secondary current in the conductor winding, wherein the negative resistance has an absolute value matching a value of a resistance of the conductor winding.

2. The feedback circuit of claim 1, wherein the conductor winding is wound around a magnetic core;
wherein the feedback circuit is configured to drive the secondary current in the conductor winding responsive to changes in a magnetic flux developed in the magnetic core in response to a primary current flowing in a conductor passed through the magnetic core.

3. The feedback circuit of claim 2, further comprising an amplifier having an input coupled to the second terminal and an output coupled to the first terminal, wherein the amplifier is configured to force a derivative of the magnetic flux to zero by forcing an inductance voltage of the conductor winding to zero while driving the secondary current in the conductor winding.

4. The feedback circuit of claim 3, further comprising an AC coupling network coupled between the second terminal and the first input of the amplifier, and configured to force a DC current in the conductor winding to zero.

5. The feedback circuit of claim 3, further comprising:
a sense resistor coupled to the second terminal, and configured to develop an input voltage at the second terminal by conducting the sense current.

6. The feedback circuit of claim 5, wherein the amplifier is configured to amplify the input voltage, and drive the amplified version of the input voltage at the first terminal;
wherein responsive to the amplifier driving the amplified version of the input voltage at the first terminal, a transformer voltage developed across the first terminal and the second terminal has a value equivalent to:
a value of the secondary current multiplied by the value of the resistance of the conductor winding.

7. The feedback circuit of claim 6, further comprising a resistor circuit coupled between a second input of the amplifier and the output of the amplifier, and configured to determine a gain of the amplifier.

8. The feedback circuit of claim 7, wherein the resistor circuit comprises:
a first resistor having a value equivalent to a multiple of the value of the resistance of the conductor winding, the first resistor having a first terminal coupled to the second input of the amplifier, and a second terminal coupled to the output of the amplifier; and
a second resistor having a value equivalent to a multiple of a value of the sense resistor, the second resistor having a first terminal coupled to the second input of the amplifier, and a second terminal coupled to a voltage reference.

9. The feedback circuit of claim 7, wherein the resistor circuit comprises one or more of:
a programmable digital potentiometer configured to compensate for a baseline uncertainty of the conductor winding; or
a thermistor configured to compensate for a temperature change of the conductor winding.

10. A method for performing measurements using a circuit comprising a current transformer having a magnetic core and a conductor winding around the magnetic core, the method comprising:
driving a secondary current in the conductor winding through a feedback circuit having:
a first terminal of two terminals coupled to a first end of two ends of the conductor winding; and
a second terminal of the two terminals coupled to a second end of the two ends of the conductor winding; and
developing a negative resistance across the two ends of the conductor winding responsive to said driving the secondary current, wherein the negative resistance has an absolute value matching a value of a resistance of the conductor winding.

11. The method of claim 10, further comprising:
driving a primary current in a conductor passed through the magnetic core;
wherein said driving the secondary current in the conductor winding is performed responsive to changes in a magnetic flux developed in the magnetic core in response to said driving the primary current.

12. The method of claim 10, wherein said developing the negative resistance comprises:
forcing a derivative of a magnetic flux developed in the magnetic core to zero, comprising forcing an inductance voltage of the conductor winding to zero while driving the secondary current in the conductor winding.

13. The method of claim 10, further comprising:
forcing a DC current in the conductor winding to zero.

14. The method of claim 10, wherein said developing the negative resistance comprises:
developing an input voltage at the second terminal by having a sense resistor conduct the sense current.

15. The method of claim 14, wherein said developing the negative resistance further comprises:
developing a transformer voltage across the first terminal and the second terminal by amplifying the input voltage and driving the amplified version of the input voltage at the first terminal;
wherein the transformer voltage has a value equivalent to a value of the secondary current multiplied by the value of the resistance of the conductor winding.

16. The method of claim 15, wherein said amplifying is performed using an amplifier circuit comprising:
an amplifier having:
a first input configured to receive the input voltage;
a second input; and
an output coupled to the first terminal; and
a resistor circuit coupled between the second input of the amplifier and the output of the amplifier, and configured to determine a gain of the amplifier.

17. The method of claim 16, wherein the resistor circuit comprises:
a first resistor having a value equivalent to a multiple of the value of the resistance of the conductor winding, the first resistor having a first terminal coupled to the second input of the amplifier, and a second terminal coupled to the output of the amplifier; and
a second resistor having a value equivalent to a multiple of a value of the sense resistor, the second resistor having a first terminal coupled to the second input of the amplifier, and a second terminal coupled to a voltage reference.

18. The method claim 16, further comprising one or more of:
compensating for a baseline uncertainty of the conductor winding through a programmable digital potentiometer configured in the resistor circuit; or
compensating for a temperature change of the conductor winding through a thermistor configured in the resistor circuit.

19. A measurement system comprising:
a measurement circuit comprising:
a current transformer having a magnetic core and a conductor winding around the magnetic core, wherein the conductor winding has a first end and a second end; and
a feedback circuit having a first terminal coupled the first end of the conductor winding, and a second terminal coupled to the second end of the conductor winding, wherein the feedback circuit is configured to develop a negative resistance across the two ends of the conductor winding by driving a secondary current in the conductor winding, wherein the negative resistance has an absolute value matching a value of a resistance of the conductor winding.

20. The measurement system of claim 19, further comprising:
a conductor passing through the magnetic core, and configured to conduct a primary current;
wherein the feedback circuit is configured to drive the secondary current in the conductor winding responsive to changes in a magnetic flux developed in the magnetic core in response to the conductor conducting the primary current.

21. The measurement system of claim 20, wherein the feedback circuit comprises an amplifier having a first input coupled to the second terminal, and an output coupled to the first terminal, wherein the amplifier is configured to force a derivative of the magnetic flux to zero by forcing an inductance voltage of the conductor winding to zero while driving the secondary current in the conductor winding.

22. The measurement system of claim 21, wherein the feedback circuit further comprises a coupling circuit coupled between the second terminal and the first input of the amplifier, and configured to force a DC current in the conductor winding to zero.

23. The measurement system of claim 21, wherein the feedback circuit further comprises:
a sense resistor coupled to the second terminal, and configured to develop an input voltage at the second terminal by conducting the sense current.

24. The measurement system of claim 23, wherein the amplifier is configured to develop a transformer voltage across the first terminal and the second terminal by amplifying the input voltage, and driving the amplified version of the input voltage at the first terminal;
wherein the transformer voltage has a value equivalent to a value of the secondary current multiplied by the value of the resistance of the conductor winding.

25. The measurement system of claim 21, further comprising a resistor circuit coupled between a second input of the amplifier and the output of the amplifier, and configured to set a gain of the amplifier.

26. The measurement system of claim 25, wherein the resistor circuit comprises:
a first resistor having a value equivalent to a multiple of the value of the resistance of the conductor winding, the first resistor having a first terminal coupled to the second input of the amplifier, and a second terminal coupled to the output of the amplifier; and
a second resistor having a value equivalent to a multiple of a value of the sense resistor, the second resistor having a first terminal coupled to the second input of the amplifier, and a second terminal coupled to a voltage reference.

27. The measurement system of claim 25, wherein the resistor circuit comprises one or more of:
a programmable digital potentiometer configured to compensate for a baseline uncertainty of the conductor winding; or
a thermistor configured to compensate for a temperature change of the conductor winding.
